(19) United States
(12) Patent Application Publication
(10) Pub. No.: US 2025/0391724 A1
(43) Pub. Date: Dec. 25, 2025

(54) POWER MODULE

(71) Applicant: Delta Electronics, Inc., Taoyuan City (TW)

(72) Inventors: Shaojun Chen, Shanghai (CN); Ying Liu, Shanghai (CN); Yanggui Feng, Shanghai (CN); Xi Liu, Shanghai (CN)

(21) Appl. No.: 19/179,831

(22) Filed: Apr. 15, 2025

(30) Foreign Application Priority Data
May 15, 2024 (CN) 202410605751.X
May 15, 2024 (CN) 202421055846.0

(51) Int. Cl. H01L 23/34; H01L 23/00

(52) U.S. Cl. CPC H01L 23/34; H01L 24/16; H01L 2224/16225

(57) ABSTRACT

A power module for supplying power to an electrical device includes a first circuit board, a second circuit board, a third circuit board and a heat-conductive element. The first, second and third circuit boards are stacked in sequence, and the heat-conductive element is disposed between the first circuit board and the second circuit board. The heat-conductive element includes a first heat-conductive portion and a second heat-conductive portion. The first heat-conductive portion extends in a direction perpendicular to a plane of the second circuit board and is in contact with a heat-dissipating element on the first circuit board. The second heat-conductive portion extends in a direction parallel to the plane of the second circuit board and is contact with heat-generating components on the second circuit board. The first and the second heat-conductive portions are connected to each other.

### CROSS-REFERENCE TO RELATED APPLICATIONS

This non-provisional application claims priorities to China Patent Application No. 202410605751.X filed on May 15, 2024 and China Patent Application No. 202421055846.0 filed on May 15, 2024. The entire contents of applications are incorporated herein by reference for all purposes.

### TECHNICAL FIELD

The present disclosure relates to the field of power electronics, and more particularly to a power module with a vertical power delivery architecture.

### BACKGROUND

Power modules with a vertical power delivery architecture are gradually adopted by integrated systems in the field of power electronics due to the excellent performance thereof.

The current vertical power delivery power module employs a two-board stacked architecture. Please refer to FIG. 1 and FIG. 2. FIG. 1 illustrates a side view of the conventional power module with the two-board stacked architecture, and FIG. 2 illustrates a schematic view of the assembly between the conventional power module (with two-board stacked architecture) and the electrical device. A power module 10 is integrated by vertically stacking a circuit board 1 and a circuit board 12, and is electrically connected to a system board 21 of an electrical device 20 via BGA (Ball Grid Array) solder balls 13. The power module 10 and a power supplied unit 22 of the electrical device 20 are arranged at the opposite sides of the system board 21.

The current vertical power delivery power module is widely used in the field of power electronics due to the advantages of short power delivery path and low power loss. However, with the developments of related industries, the size of the vertical power delivery power module is requested to be smaller, and accordingly, the heat dissipation issue of the power module also becomes an important issue due to the reduced size thereof.

Therefore, there is a need of providing a vertical power delivery power module for solving the drawbacks above.

### SUMMARY

An object of the present disclosure is to provide a power module with a reduced occupied area and high heat dissipation efficiency.

In accordance with an aspect of the present disclosure, a power module for supplying power to an electrical device is provided. The power module includes a first circuit board, a second circuit board, a third circuit board and a heat-conductive element. The first circuit board has a heat-dissipating element disposed thereon. The second circuit board is stacked with and connected to the first circuit board, wherein the second circuit board has at least one heat-generating component disposed thereon. The heat-dissipating element and the at least one heat-generating component are respectively disposed on opposing surfaces of the first circuit board and the second circuit board. The third circuit board is stacked with and connected to the second circuit board, as well as connected to the electrical device. The heat-conductive element is disposed between the first circuit board and the second circuit board. The heat-conductive element includes a first heat-conductive portion and a second heat-conductive portion. The first heat-conductive portion extends in a direction perpendicular to a plane of the second circuit board, and is in contact with the heat-dissipating element on the first circuit board. The second heat-conductive portion extends in a direction parallel to the plane of the second circuit board, and is contact with the at least one heat-generating component on the second circuit board. The first heat-conductive portion and the second heat-conductive portion are connected to each other.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a side view of the conventional power module with a two-board stacked architecture;

FIG. 2 is a schematic view of the assembly between the conventional power module (with two-board stacked architecture) and the electrical device;

FIG. 3A is an exploded schematic view of a power module according to an embodiment of the present disclosure;

FIG. 3B is an exploded schematic view of the power module according to the embodiment of the present disclosure from another view angle;

FIG. 4A is a schematic view of a heat-conductive element according to an embodiment of the present disclosure;

FIG. 4B a schematic view of the heat-conductive element according to the embodiment of the present disclosure from another view angle; and

FIG. 5 is a schematic view of heat-conductive paths between the heat-conductive element and heat-generating components in the power module according to an embodiment of the present disclosure.

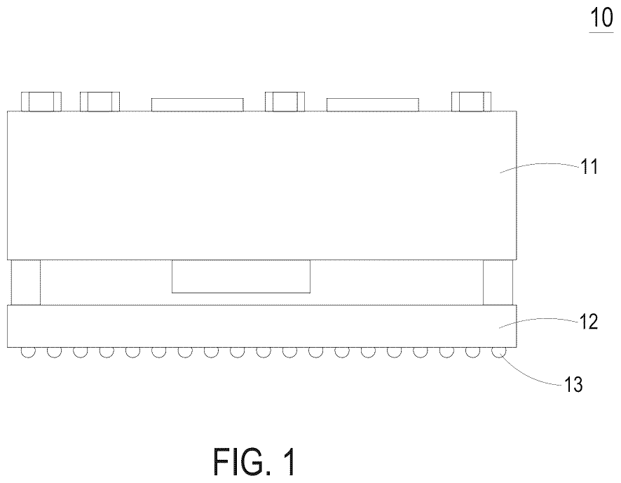

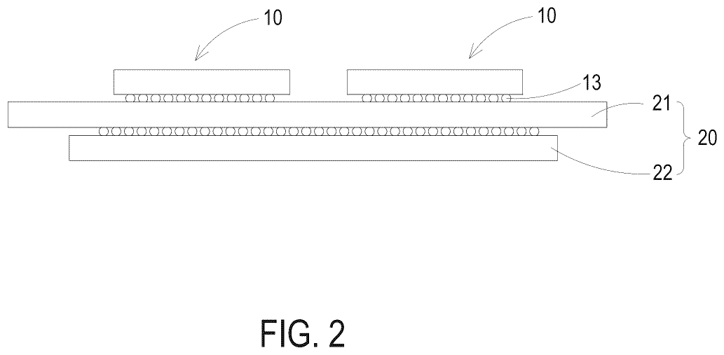

### DETAILED DESCRIPTION OF EMBODIMENTS

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed.

Notably, when an element is referred to as being “connected” or “coupled” to another element, such connection or coupling may be: (i) fixed, removable or integrated; (ii) mechanical or electrical; (iii) direct or indirect with intervening elements.

Reference will be made in detail to the accompanying drawings and embodiments of the present disclosure. The embodiments are based on the technical solutions of the present disclosure, but the protection scope of the present disclosure is not limited to the following embodiments.

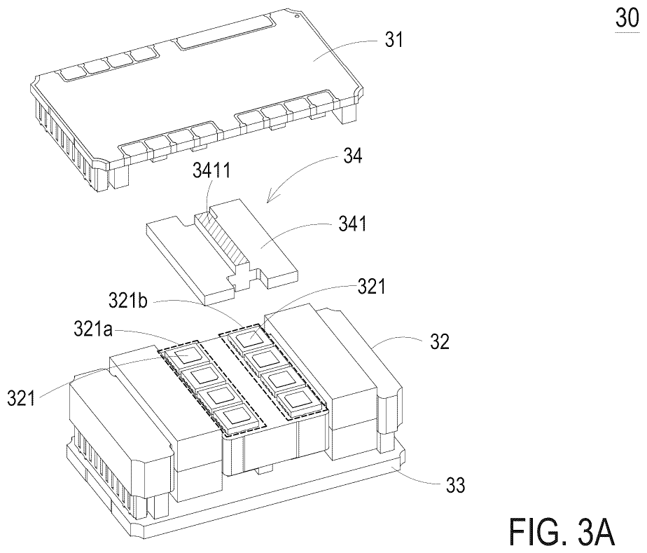

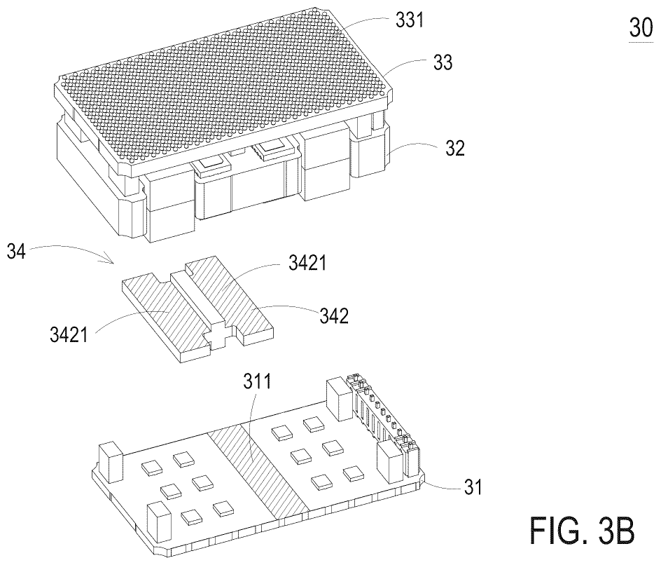

Please refer to FIG. 3A and FIG. 3B. FIG. 3A is an exploded schematic view of a power module according to an embodiment of the present disclosure, and FIG. 3B is an exploded schematic view of the power module according to the embodiment of the present disclosure from another view angle. The present disclosure provides a power module 30 with three vertically stacked circuit boards. The power module 30 includes a first circuit board 31, a second circuit board 32 and a third circuit board 33 which are vertically stacked in sequence. The first circuit board 31 and the second circuit board 32 are connected to each other, and the second circuit board 32 and the third circuit board 33 are connected to each other. BGA (Ball Grid Array) solder balls 331 are disposed on one surface of the third circuit board 33 opposite to the second circuit board 32 for connecting to an electrical device (not shown) for power supplying.

Unlike conventional power module with two stacked circuit boards, the power module 30 of the present disclosure employs three stacked circuit boards, so that electronic components can be distributed and arranged on the three circuit boards. Therefore, compared with the conventional power module, under the same output power, the power module 30 of the present disclosure can significantly reduce its overall size and the occupied area on the system board of the electrical device. This results in an enhanced integration of the electrical device system.

For the power module with three vertically stacked circuit boards, the heat dissipation of electronic components on the intermediate circuit board (the second circuit board 32) is an important issue. Since the size of the power module 30 is small and the number of electronic components inside the power module is high, the difficulty in dissipating the heat generated from the electronic components on the second circuit 32 may adversely affect the performance of the power module 30. To address this issue, the present disclosure provides a heat-conductive element 34 disposed between the first circuit board 31 and the second circuit board 32, and heat-generating components 321 on the second circuit board 32 are arranged on a surface of the second circuit board 32 facing the first circuit board 31, while a heat-dissipating element 311 is disposed on a surface of the first circuit board 31 facing the second circuit board 32. Accordingly, heat generated by the heat-generating components 321 can be transmitted to the heat-dissipating element 311 on the first circuit board 31 through the heat-conductive element 34 first and then dissipated into the air, thereby improving the heat dissipation performance of the second circuit board 32. In some embodiments, the heat-dissipating element 311 includes a metal sheet, such as a copper sheet. In some embodiments, the heat-generating components 321 include a magnetic core or a power semiconductor switch etc.

Notably, in practice, electronic components on the first circuit board 31 or the third circuit board 33 also generate heat; however, since the heat can be dissipated more easily, the heat-generating components mentioned in the present disclosure are particularly referred to those disposed on the second circuit board 32.

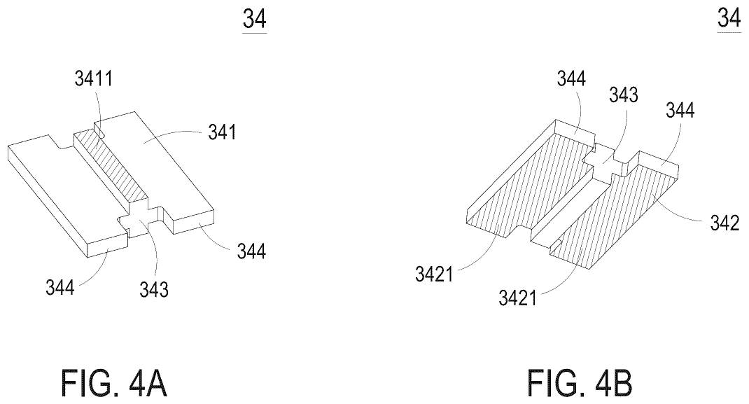

Please refer to FIG. 3A to FIG. 3B and FIG. 4A to FIG. 4B. FIG. 4A is a schematic view of the heat-conductive element according to an embodiment of the present disclosure, and FIG. 4B a schematic view of the heat-conductive element according to the embodiment of the present disclosure from another view angle. The heat-conductive element 34 includes a first heat-conductive portion 343 and a second heat-conductive portion 344, wherein the first heat-conductive portion 343 extends in a direction perpendicular to the plane of the second circuit board 32, and the second heat-conductive portion 344 extends in a direction parallel to the plane of the second circuit board 32 and extends from two opposite sides of the first heat-conductive portion 343. That is, the heat-conductive element 34 is configured as a laterally extending wing-shaped structure. Moreover, the heat-conductive element 34 includes a first surface 341 facing the first circuit board 31 and a second surface 342 facing the second circuit board 32. The first surface 341 includes a first contacting region 3411 for contacting with the heat-dissipating element 311 on the first circuit board 31. The second surface 342 includes second contacting regions 3421 for contacting with the heat-generating components 321 on the second circuit board 32.

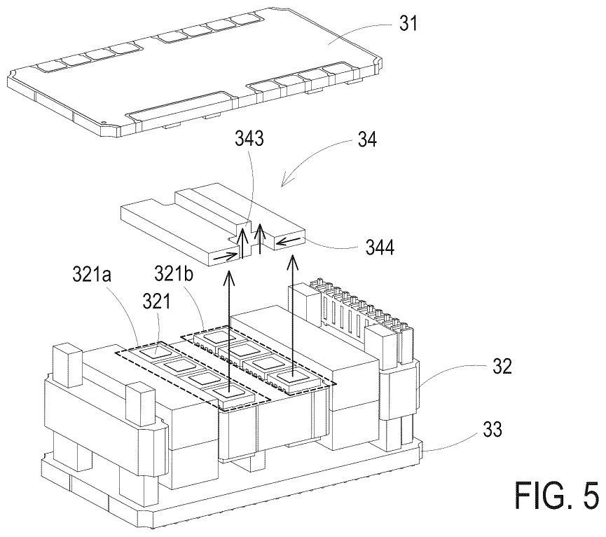

Please refer to FIG. 5 which is a schematic view of heat-conductive paths between the heat-conductive element and heat-generating components in the power module according to an embodiment of the present disclosure. As shown by arrows in FIG. 5, heat generated by the heat-generating components 321 on the second circuit board 32 is transferred to the second heat-conductive portion 344 first. Then, it is transferred to the heat-dissipating element 311 of the first circuit board 31 via the first heat-conductive portion 343, and finally dissipated into the air.

In some embodiments, the projection area of the first heat-conductive portion 343 on the plane of the second circuit board 32 is less than the projection area of the second heat-conductive portion 344 on the plane of the second circuit board 32, namely, the projection area of the second contacting region 3421 is greater than the projection area of the first contacting region 3411. Under this configuration, the second heat-conductive portion 344 can cover more heat-generating components on the second circuit board 32, while minimizing the space of the first circuit board 31 occupied by the first heat-conductive portion 343. This allows for simultaneous reduction of the overall size of the power module 30 and improvement of the heat dissipation efficiency, which is advantageous for optimizing the design.

In some embodiments, the first heat-conductive portion 343 is in contact with the second circuit board 32, thereby reducing the stress from the first circuit board 31 and protecting the heat-generating components 321 on the second circuit board 32.

In some embodiments, the second heat-conductive portion 344 may be disposed on either side of the first heat-conductive portion 343 or two opposite sides of the first heat-conductive portion. Furthermore, the first heat-conductive portion 343 and the second heat-conductive portion 344 may be implemented as two independent portions or may be integrally formed as one piece.

The whole heat-conductive element 34 is made of heat conductive material. Therefore, even if the projection areas of the first contacting region 3411 and the second contacting region 3421 are unequal, the heat from the heat-generating components 321 can still be smoothly transferred into the heat-conductive element 34 via the second contacting region 3421. It is then conducted through the heat-conductive element 34, and finally transferred to the heat-dissipating element 311 via the first contacting region 3411. The heat-conductive element 34 can be a metal heat-conductive element, such as copper, aluminum etc.; or the heat-conductive element 34 can be a non-metal heat-conductive element, such as heat conductive ceramic, heat conductive silicon etc.; or the heat-conductive element can be fabricated from any kind of heat-conductive material.

Moreover, multiple heat-generating components 321 on the second circuit board 32 can be arranged into separate heat source arrays 321a and 321b, and the second heat-conductive portion 344 correspondingly contacts the heat source arrays 321a and 321b respectively. Based on the structure that the second heat-conductive portion 344 and the first heat-conductive portion 343 extend in different directions, the second heat-conductive portion 344 can be designed to align with the positions and shapes of the heat-generating components 321 (or heat source arrays 321a, 321b). This eliminates the need to consider the position and size of the heat-dissipating element 311 on the first circuit board 31 and the layout of other electronic components. In other words, the shape of the heat-conductive element 34 in the present disclosure can be adjusted in accordance with the positions of the heat-generating components 321 and the heat source arrays 321a, 321b on the second circuit board 32, and the position of the heat-dissipating element 311 on the first circuit board 31, thereby minimizing the influence on the arrangement of other electronic components on each circuit board.

Furthermore, in order to optimize the contact between the heat-conductive element 34 and the heat-generating components 321, the heat-generating components 321 can be arranged according to their heights. This ensures that heat-generating components 321 with similar or identical heights are grouped within each respective heat source array. For example, as shown in FIG. 3A, the heat-generating components 321 in the heat source array 321a have similar or identical heights, and the heat-generating components 321 in the heat source array 321b have similar or identical heights.

In addition, the heat-conductive element 34 and the heat dissipating element 311 can be configured to contact directly, by disposing thermal paste between them, or by fixing together via soldering, screwing etc. Similarly, the heat-conductive element 34 and the heat-generating components 321 also can be configured to contact directly, by disposing thermal paste between them, or by fixing together through soldering, screwing etc. Therefore, it can be varied in accordance with the practical situations.

In conclusion, the present disclosure, different from the prior art, provides the power module employing the architecture of three vertically stacked circuit boards. In this architecture, the number of circuit boards for distributing and arranging the heat-generating components is increased, and the heat-conductive element is further disposed between the circuit boards. This configuration achieves the purposes of reducing overall occupied area of the power module and simultaneously improving heat dissipation efficiency.

It is to be understood that the disclosure needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A power module for supplying power to an electrical device, comprising:
a first circuit board with a heat-dissipating element disposed thereon;
a second circuit board stacked with and connected to the first circuit board, wherein the second circuit board has at least one heat-generating component disposed thereon, the heat-dissipating element and the at least one heat-generating component are respectively disposed on opposing surfaces of the first circuit board and the second circuit board that face each other;
a third circuit board stacked with and connected to the second circuit board, and connected to the electrical device; and
a heat-conductive element disposed between the first circuit board and the second circuit board, comprising:
a first heat-conductive portion extending in a direction perpendicular to a plane of the second circuit board, and in contact with the heat-dissipating element on the first circuit board; and
a second heat-conductive portion extending in a direction parallel to the plane of the second circuit board, and in contact with the at least one heat-generating component on the second circuit board,
wherein the first heat-conductive portion and the second heat-conductive portion are connected to each other.

2. The power module as claimed in claim 1, wherein a projection area of the first heat-conductive portion on the plane of the second circuit board is less than a projection area of the second heat-conductive portion on the plane of the second circuit board.

3. The power module as claimed in claim 1, wherein the first heat-conductive portion is in contact with the second circuit board.

4. The power module as claimed in claim 1, wherein the second heat-conductive portion is disposed on either side or two opposite sides of the first heat-conductive portion.

5. The power module as claimed in claim 1, wherein the first heat heat-conductive and the second heat-conductive portion are integrally formed as one piece.

6. The power module as claimed in claim 1, wherein the at least one heat-generating component is implemented as a plurality of heat-generating components, the plurality of heat-generating components are arranged into at least one heat source array, and the second heat-conductive portion is in contact with the at least one heat source array.

7. The power module as claimed in claim 1, wherein the heat-dissipating element comprises a metal sheet.

8. The power module as claimed in claim 1, wherein the heat-conductive element comprises a metal heat-conductive element or a non-metal heat-conductive element.

9. The power module as claimed in claim 1, wherein the at least one heat-generating component comprises a magnetic core or a power semiconductor switch.

10. The power module as claimed in claim 1, wherein a plurality of BGA (Ball Grid Array) solder balls are disposed on a surface of the third circuit board facing the electrical device for electrically connecting to the electrical device.
